(19) United States
(12) Patent Application Publication
(10) Pub. No.: US 2025/0014953 A1
(43) Pub. Date: Jan. 9, 2025

(54) SEMICONDUCTOR PACKAGE AND METHOD OF MANUFACTURING THE SAME

(71) Applicant: Samsung Electronics Co., Ltd., Suwon-si (KR)

(72) Inventors: Duckgyu Kim, Suwon-si (KR); Sanguk Han, Suwon-si (KR)

(21) Appl. No.: 18/764,401

(22) Filed: Jul. 5, 2024

(30) Foreign Application Priority Data
Jul. 7, 2023 (KR) 10-2023-0088631

(51) Int. Cl. H01L 23/13; H01L 21/48; H01L 21/78; H01L 23/498

(52) U.S. Cl. CPC H01L 23/13; H01L 21/4857; H01L 21/78; H01L 23/49822

(57) ABSTRACT

Provided is a semiconductor package including a rewiring structure including a rewiring pattern, and at least one insulating layer, a semiconductor device provided on the rewiring structure, and electrically connected to the rewiring pattern, and a side surface protector covering a first side surface of the semiconductor device, wherein an upper surface of the semiconductor device that is opposite to a lower surface of the semiconductor device facing the rewiring structure and an upper surface of the side surface protector are at the same vertical level and are coplanar with each other, and the side surface protector extends from the insulating layer of the rewiring structure.

### CROSS-REFERENCE TO RELATED APPLICATION

This application is based on and claims priority under 35 U.S.C. § 119 to Korean Patent Application No. 10-2023-0088631, filed on Jul. 7, 2023, in the Korean Intellectual Property office, the disclosure of which is incorporated by reference herein in its entirety.

### BACKGROUND

The inventive concept relates to a semiconductor package and a method of manufacturing the semiconductor package.

In the general process of manufacturing a semiconductor package, a rewiring structure and a connection terminal are formed on a semiconductor substrate, and a portion of the semiconductor substrate may be removed by using a back lap process, and then a singulation process may be performed to singulate the semiconductor packages. By using the singulating process, the semiconductor substrate may be individualized as a semiconductor device or a semiconductor package.

### SUMMARY

The inventive concept provides a method of improving reliability of side surfaces of a semiconductor package.

Issues to be solved by the inventive concept are not limited to the above-mentioned issues, and other issues not mentioned may be clearly understood by those of ordinary skill in the art from the following descriptions.

According to an aspect of the inventive concept, there is provided a semiconductor package including a rewiring structure including a rewiring pattern and at least one insulating layer, a semiconductor device provided on the rewiring structure and electrically connected to the rewiring pattern, and a side surface protector covering a first side surface of the semiconductor device and extending to a side surface of the rewiring structure, wherein an upper surface of the semiconductor device, which is opposite to a lower surface of the semiconductor device facing the rewiring structure, and an upper surface of the side surface protector are at the same vertical level and are coplanar with each other, and the side surface protector extends from the insulating layer of the rewiring structure.

In addition, according to another aspect of the inventive concept, there is provided a method of manufacturing a semiconductor package including performing a first singulation process on a substrate that includes devices formed thereon, forming a rewiring layer (RDL) on the substrate and a side surface protector on a region on the substrate where the first singulation process has been performed, and performing a back lap process on a rear surface of the substrate.

In addition, according to another aspect of the inventive concept, there is provided a semiconductor package including a rewiring structure including a rewiring pattern including a rewiring via pattern and a rewiring line pattern, and at least one insulating layer, a semiconductor device provided on the rewiring structure and electrically connected to the rewiring pattern, and a side surface protector covering a first side surface of the semiconductor device, a first uneven surface included in the first side surface, a second side surface protruding beyond the first side surface, and a second uneven surface included in the second side surface, wherein an upper surface of the semiconductor device opposite to a lower surface of the semiconductor device facing the rewiring structure and an upper surface of the side surface protector are at the same vertical level and are coplanar with each other, and the side surface protector extends from the insulating layer of the rewiring structure, wherein a first exposed side surface of the side surface protector that is opposite to a surface in contact with the first side surface has an even surface without unevenness, and a second exposed side surface, which is opposite to a surface in contact with the second side surface of the side surface protector, has an even surface without unevenness, wherein the first exposed side surface is coplanar with the second exposed side surface, and the surfaces of the first exposed side surface and the second exposed side surface extend toward one another, wherein the first uneven surface includes cracks resulting from a singulation process of the semiconductor device, and wherein the insulating layer and the side surface protector are comprised of the same material.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is a cross-sectional view of a semiconductor package according to an embodiment;

FIG. 3 is a cross-sectional view of a semiconductor package according to an embodiment;

FIG. 4 is a flowchart of a method of manufacturing a semiconductor package, according to an embodiment;

FIG. 5 is a cross-sectional view illustrating a method of manufacturing a semiconductor package, according to an embodiment;

FIG. 6 is a cross-sectional view illustrating a method of manufacturing a semiconductor package, according to an embodiment;

FIG. 7 is a cross-sectional view illustrating a method of manufacturing a semiconductor package, according to an embodiment;

FIG. 8 is a cross-sectional view illustrating a method of manufacturing a semiconductor package, according to an embodiment; and

FIG. 9 is a cross-sectional view illustrating a method of manufacturing a semiconductor package, according to an embodiment.

### DETAILED DESCRIPTION OF THE EMBODIMENTS

Hereinafter, example embodiments of the inventive concept are described in detail with reference to the accompanying drawings. The same reference numerals are used for the same constituent elements in the drawings, and duplicate descriptions thereof may be omitted.

As used herein, the singular forms “a”, “an” and “the” are intended to include the plural forms as well, unless the context clearly indicates otherwise. As used herein, the term “and/or” includes any and all combinations of one or more of the associated listed items and may be abbreviated as “/”.

It will be appreciated that “planarization,” “co-planar,” “planar,” etc., as used herein refer to structures (e.g., surfaces) that need not be perfectly geometrically planar, but may include acceptable variances that may result from standard manufacturing processes. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

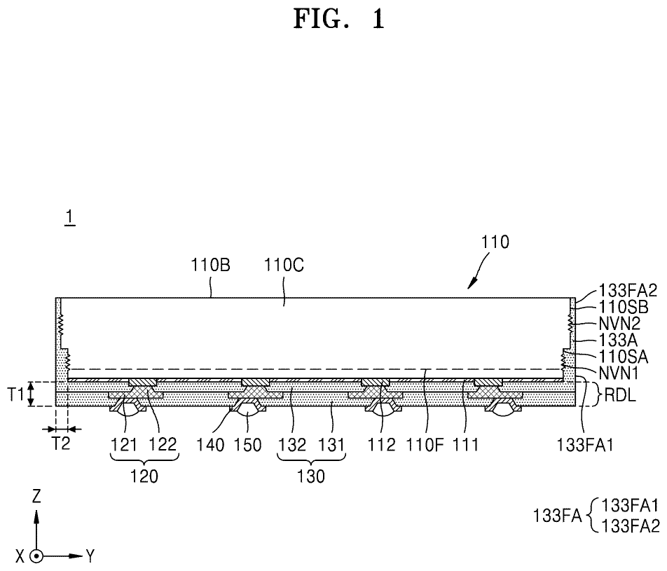

FIG. 1 is a cross-sectional view of a semiconductor package 1 according to an embodiment.

Referring to FIG. 1, the semiconductor package 1 according to an embodiment may include a semiconductor device 110, a rewiring structure RDL, on which the semiconductor device 110 is mounted, and a side surface protector 133A covering side surfaces of the semiconductor device 110. The side surface protector 133A may extend beyond the side surfaces of the semiconductor device to cover side surfaces of the rewiring structure RDL.

The semiconductor package 1 may include a fan in type semiconductor package, in which a horizontal width and a horizontal area of the rewiring structure RDL are approximately the same as a horizontal width and a horizontal area of a semiconductor device 110, respectively. In the inventive concept, “horizontal” may mean an X-Y plane, a first horizontal direction may mean an X direction, and a second horizontal direction may mean a Y direction. “Vertical” may mean a direction perpendicular to the X-Y plane, and a “vertical direction” may mean a Z direction. The X-Y plane may be defined as a plane that is parallel to a lower surface of the semiconductor device as shown in the figures.

In some embodiments, the rewiring structure RDL may be formed using a rewiring process. In the inventive concept, the rewiring structure RDL may form a substrate for the semiconductor package 1 and may be referred to as a package substrate. The rewiring structure RDL may include a rewiring insulating layer 130 and a plurality of rewiring patterns 120. The rewiring insulating layer 130 may surround the plurality of rewiring patterns 120. Each rewiring pattern 120 of the plurality of rewiring patterns 120 may be electrically insulated from one another by the insulating layer 130. In some embodiments, the rewiring structure RDL may include a plurality of rewiring insulating layers 130. For example, a first rewiring insulating layer 131 adjacent to the semiconductor device 110, and a second rewiring insulating layer 132 arranged on the first rewiring insulating layer 131 may be provided. In addition, two or more rewiring insulating layers may be included in the rewiring structure RDL. The rewiring insulating layer 130 may be formed of and/or include a photo imageable dielectric material. The rewiring insulating layer 130 may be formed of and/or include, for example, a photo sensitive polymer. The photo sensitive polymer may include, for example, at least one of photosensitive polyimide, polybenzoxazole, phenol-based polymer, and benzocyclobutene-based polymer.

The plurality of rewiring patterns 120 may include a plurality of rewiring line patterns 121 and a plurality of rewiring via patterns 122 (e.g., each rewiring pattern 120 of the plurality of rewiring patterns 120 may include at least one rewiring line pattern 121 and at least one rewiring via pattern 122). The plurality of rewiring patterns 120 may be formed of and/or include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), or an alloy thereof, but are not limited thereto.

The plurality of rewiring line patterns 121 may be arranged on at least one of an upper surface and a lower surface of the rewiring insulating layer 130. For example, when a rewiring structure RDL includes a plurality of rewiring insulating layers 130, the plurality of rewiring line patterns 121 may be located between the upper surface of the rewiring insulating layer 130 at the uppermost end of the rewiring structure RDL and the lower surface of the rewiring insulating layer 130 at the lowermost end of the rewiring structure RDL. For example, a rewiring line pattern may be located between adjacent rewiring insulating layers 130 of the plurality of rewiring insulating layers 130.

The plurality of rewiring via patterns 122 may penetrate vertically through the rewiring insulating layer 130 and each rewiring via pattern 122 may be connected to at least one of the plurality of rewiring line patterns 121. In some embodiments, at least one of the plurality of rewiring via patterns 122 may have a tapered shape in which a horizontal width thereof increases as the rewiring via pattern 122 extends in a direction away from the semiconductor device 110. The tapered shape of a rewiring via pattern 122 may have a horizontal width that may vary depending on the forming process of the first rewiring structure RDL, but the inventive concept is not limited to embodiments having the shape described herein.

In some embodiments, some of the plurality of rewiring via patterns 122 may be initially formed as one body together with some of the plurality of rewiring line patterns 121 (e.g., may be formed at the same time using the same material and the same process). For example, a rewiring line pattern 121 and a rewiring via pattern 122 in contact with a lower surface of the rewiring line pattern 121 may be formed in one body together.

A plurality of lower connection pads 140 may include an under bump metal (UBM). A plurality of external connection terminals 150 may be respectively attached to the plurality of lower connection pads 140. In some embodiments, the plurality of external connection terminals 150 may include solder bumps or solder balls. The plurality of external connection terminals 150 may connect the semiconductor package 1 to a separate external substrate. The separate external substrate may be electrically connected to the semiconductor device 110 via the plurality of external connection terminals 150. The separate external substrate may include a printed circuit board (PCB) substrate, an interposer, etc.

The semiconductor device 110 may be provided on the rewiring structure RDL. The semiconductor device 110 may include a semiconductor substrate 110C including an active surface 110F and an inactive surface 110B facing away from the active surface, a front end of line (FEOL) layer formed on the active surface 110F of the semiconductor substrate 110C, a back end of line (BEOL) layer provided under the FEOL layer, and a plurality of chip pads 112 arranged on a first surface of the semiconductor device 110. The inactive surface 110B may be referred to as a second surface and the first surface may be an opposing surface of the semiconductor device 110. The active surface 110F of the semiconductor substrate 110C may be adjacent to the first surface of the semiconductor device 110. In some examples, the semiconductor device 110 may have a thickness of 150 μm or more (e.g., a distance between the first surface and the second surface of the semiconductor device 110).

In some embodiments, the semiconductor device 110 may have a face down arrangement, in which the first surface of the semiconductor device 110 faces the rewiring structure RDL and the semiconductor device 110 may be mounted on the upper surface of the rewiring structure RDL. In this case, the first surface of the semiconductor device 110 may be referred to as a lower surface of the semiconductor device 110, and the second surface of the semiconductor device 110 may be referred to as an upper surface of the semiconductor device 110.

The plurality of chip pads 112 of the semiconductor device 110 may each be electrically connected to a corresponding portion of a rewiring pattern 120 of the plurality of rewiring patterns 120 of the rewiring structure RDL. For example, a first chip pad 112 may contact a corresponding portion of a first rewiring pattern 122 of the plurality of rewiring patterns 120 and a second chip pad 112 may contact a corresponding portion of a second rewiring pattern 122 of the plurality of rewiring patterns 120.

The plurality of chip pads 112 may be provided on the semiconductor device 110 by using a physical vapor deposition (PVD) process, a chemical vapor deposition (CVD) process, an electroplating process, an electroless plating process, or another metal deposition process. The plurality of chip pads 112 may be formed of and/or include at least one conductive material, such as Al, Cu, Sn, Ni, Au, Ag, Ti, or other conductive material. The plurality of chip pads 112 may be electrically connected to the BEOL layer provided in the semiconductor device 110 and transfer a signal external to the semiconductor device 110.

A passivation layer 111 may be formed on a surface of the semiconductor substrate 110C such as the lower surface of the semiconductor substrate 110C. The passivation layer 111 may cover portions of the plurality of chip pads 112 and surround side surfaces of the plurality of chip pads 112. The passivation layer 111 may be formed by using a physical vapor deposition (PVD) process, a chemical vapor deposition (CVD) process, a printing process, a spin coating process, a spray coating process, a sintering process, or a thermal oxidation process.

The semiconductor substrate 110C may be formed of and/or include, for example, a semiconductor material, such as silicon (Si) and germanium (Ge). Alternatively, the semiconductor substrate 110C may be formed of and/or include a compound semiconductor material, such as silicon carbide (SiC), gallium arsenide (GaAs), indium arsenide (InAs), and indium phosphate (InP). The semiconductor substrate 110C may include a conductive region, such as a well doped with impurities. The semiconductor substrate 110C may have various element isolation structures such as a shallow trench isolation (STI) structure.

A semiconductor device including a plurality of individual devices of various types may be formed on the active surface 110F of the semiconductor substrate 110C. The plurality of individual devices may be electrically connected to the conductive region of the semiconductor substrate 110C. The semiconductor device may further include a conductive wiring or a conductive plug electrically connecting the plurality of individual devices to the conductive region of the semiconductor substrate 110C. In addition, each of the plurality of individual devices may be electrically isolated from another adjacent individual device by an insulating layer.

In some embodiments, the semiconductor device 110 may include a logic device. For example, the semiconductor device 110 may include a central processing unit chip, a graphics processing unit chip, or an application processor (AP). In some other embodiments, when the semiconductor package 1 includes a plurality of internal semiconductor devices 110, one of the plurality of semiconductor devices 200 may include a central processing unit chip, a graphics processing unit chip, or an AP chip, and the other internal semiconductor devices 200 may include a memory semiconductor chip including a memory device.

For example, the memory device may include, for example, a non-volatile memory device, such as flash memory, phase change random access memory (RAM) (PRAM), magnetic RAM (MRAM), ferroelectric RAM (FeRAM), and resistive RAM (RRAM). In some embodiments, the memory device may include a volatile memory device, such as dynamic RAM (DRAM) and static RAM (SRAM).

In a process of manufacturing the semiconductor device 110, the semiconductor device 110 may undergo a singulation process for separating semiconductor devices 110 on a common substrate from one another. Examples of singulation processes include a cutting process and a sawing process. In the following description, a sawing process will be used as an example with the understanding that other singulating processes may be used. For example, a sawing process may be performed along a scribe lane SCL region to be described below to singulate a semiconductor device 110 or a semiconductor package 1. When a sawing process is performed on a substrate on which a plurality of semiconductor devices are provided to singulate a semiconductor device, the sawing process may cause a crack to occur on a sidewall of at least one of the plurality of semiconductor devices on the substrate for which the sawing process has been performed. In the present disclosure a surface on which the crack has occurred may be referred to as an uneven surface.

The semiconductor package 1, in some embodiments, may undergo a first sawing process and a second sawing process. The first sawing process may cause a first uneven surface NVN1 to be formed on a first side surface 110SA of the semiconductor substrate 110C. After the first sawing process is performed, a second sawing process, which is performed at a deeper depth than the first sawing process, may be performed which may form a second uneven surface NVN2 on a second side surface 110SB of the semiconductor substrate 110C. The second side surface 110SB, which is the side surface of the semiconductor substrate 110C with the second uneven surface NVN2 resulting from the second sawing process, may protrude more than the first side surface 110SA, which is the side surface of the semiconductor substrate 110C with the first uneven surface NVN1 formed thereon resulting from the first sawing process. For example, the side surface of the semiconductor substrate 110C may have a step shape due to the second side surface 110SB protruding farther horizontally than the first side surface 110SA.

The side surface protector 133A may cover all of the first side surface 110SA, the first uneven surface NVN1 of the first side surface 110SA, the second side surface 110SB, the second uneven surface NVN2 of the second side surface 110SB, and the side surface of the rewiring structure RDL.

In the following description, an insulating layer 130 and the side surface protector 133A of the rewiring structure RDL are separate elements and are referred to individually, but in the manufacturing processes to be described below, the insulating layer 130 and the side surface protector 133A of the rewiring structure RDL may be formed using the same manufacturing process. Thus, the insulating layer 130 may not be clearly differentiated from the side surface protector 133A of the rewiring structure RDL. Both the insulating layer 130 and the side surface protector 133A may extend toward one another. The side surface protector 133A may be formed of and/or include the same material as the insulating layer 130 of the rewiring structure RDL. In an embodiment, the side surface protector 133A may be formed of and/or include photo imageable dielectric (PID) or photosensitive polyimide (PSPI).

The upper surface of the side surface protector 133A, may be coplanar with the inactive surface 110B, which is the upper surface of the semiconductor substrate 110C. For example, relative to the upper surface of the rewiring structure RDL, the vertical level of the upper surface of the side surface protector 133A may be the same as the vertical level of the inactive surface 110B (e.g., the distance between the upper surface of the rewiring structure RDL and the upper surface of the side surface protector 133A may be the same as the distance between the upper surface of the rewiring structure RDL and the inactive surface 110B) The inactive surface 110B may be coplanar with the upper surface of the side surface protector 133A as a result of a back lap process of lapping and removing an upper surface of the semiconductor device 110 after the sawing process is complete.

A first exposed side surface 133FA1 of the side surface protector 133A, which is a side surface exposed external to the semiconductor device 110 and opposes the side surface of the side surface protector 133A in contact with the first uneven surface NVN1, may have an even surface without unevenness (e.g., a smooth surface). In other words, a crack at a side surface of the semiconductor substrate 110C occurring due to processes such as a sawing process may not be formed in the first exposed side surface 133FA1. Similarly, a second exposed side surface 133FA2, which is a side surface exposed externally to the semiconductor device 110 and opposes the surface of the side surface protector 133A in contact with the second uneven surface NVN2, may have an even surface without unevenness (e.g., a smooth surface). Both the first exposed side surface 133FA1 and the second exposed side surface 133FA2 may be inclusively referred to as an exposed side surface 133FA.

As illustrated in FIG. 1, both the first exposed side surface 133FA1 and the second exposed side surface 133FA2 may extend toward one another. In addition, the first exposed side surface 133FA1 may be coplanar with the second exposed side surface 133FA2. For example, the second side surface 110SB may protrude beyond the first side surface 110SA but the second exposed side surface 133FA2 may not protrude beyond the first exposed side surface 122FA1.

In the rewiring structure RDL, a vertical direction thickness of the insulating layer 130 may be referred to as a first thickness T1 and may be the same as a distance between the first side surface 110SA and the first exposed side surface 133FA1. The first thickness may be greater than a thickness, referred to as a second thickness T2, of a portion of the side surface protector 133A covering the first uneven surface NVN1 included in the first side surface 110SA. The insulating layer 130 of the rewiring structure RDL may be formed using a coating process, such as a spin coating process and a slit coating process, a photo patterning process, and a curing process. Although the insulating layer 130 and the side surface protector 133A may be formed using the processes described above, because the side surface protector 133A is formed on the first side surface 110SA and the second side surface 110SB of the semiconductor substrate 110C which are not coplanar, unlike the insulating layer 130, the thickness of the side surface protector 133A may be less than the total thickness of the insulating layer 130 of the rewiring structure RDL. For example, the second thickness T2 of the side surface protector 133A may be about 5 μm to about 10 μm.

The semiconductor package 1 according to an embodiment of the inventive concept may, by including the side surface protector 133A provided on the side surface of the semiconductor device 110, prevent the side surface of the semiconductor device 110 from being directly exposed external to the semiconductor device 110. By using the side surface protector 133A, an external force to the side of the semiconductor package 1 may not be directly transferred to the semiconductor device 110. Because the external force is not directly applied to the semiconductor device 110, additional occurrence of side surface cracks of the semiconductor device 110 may be prevented or reduced. In addition, direct damage to a semiconductor device may be prevented or reduced.

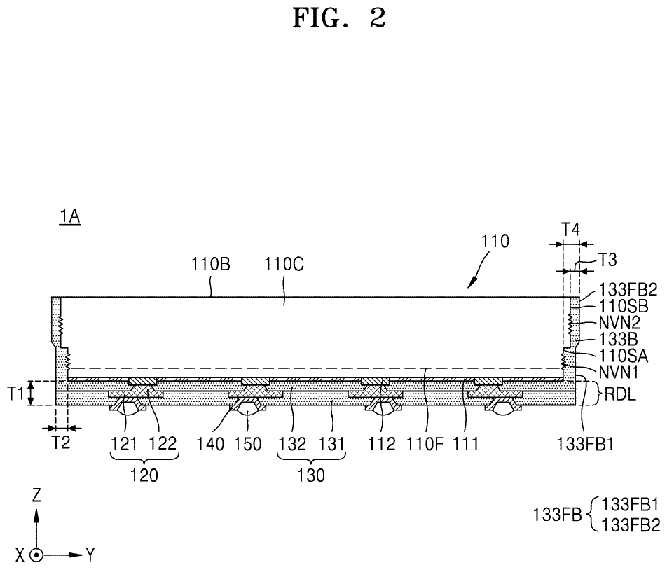

FIG. 2 is a cross-sectional view of a semiconductor package 1A according to an embodiment. Descriptions of elements that were described previously in relation to FIG. 1 may be omitted.

Referring to FIG. 2, the first side surface 110SA and the second side surface 110SB, which are side surfaces of the semiconductor substrate 110C, may be covered by a side surface protector 133B. A first exposed side surface 133FB1, which is a side surface exposed external to the semiconductor package 1 and is, opposite to a first surface of the side surface protector 133B in contact with the first uneven surface NVN1, may have an even surface without unevenness (e.g., a smooth surface). For example, a crack occurring due to processes such as a sawing process may not be formed in the first exposed side surface 133FB1. Similarly, a second exposed side surface 133FB2, which is a side surface exposed external to the semiconductor package 1A and is opposite to a second surface of the side surface protector 133B in contact with the second uneven surface NVN2, may have an even surface without unevenness (e.g., a smooth surface). Both the first exposed side surface 133FB1 and the second exposed side surface 133FB2 may be inclusively referred to as an exposed side surface 133FB.

As illustrated in FIG. 2, both the first exposed side surface 133FA1 and the second exposed side surface 133FA2 may extend towards one another. In contrast to the embodiment of FIG. 1, the first exposed side surface 133FB1 may not be coplanar with the second exposed side surface 133FB2. For example, the second side surface 110SB may protrude relative to the first side surface 110SA, and accordingly, the second exposed side surface 133FB2 may protrude relative to the first exposed side surface 133FB1.

In the rewiring structure RDL, the thickness of the insulating layer 130 in the vertical direction, referred to as a first thickness T1, may be the same as a distance between the first side surface 110SA and the first exposed side surface 133FA1, and may be greater than the thickness, referred to as a second thickness T2, of the side surface protector 133A covering the first uneven surface NVN1 included in the first side surface 110SA.

The thickness, referred to as a third thickness T3, of the side surface protector 133B covering the second uneven surface NVN2 included in the second side surface 110SB and which corresponds to a horizontal direction distance between the second side surface 110SB and the second exposed side surface 133FB2, may be equal to or less than the second thickness T2. Because the side surface protector 133B may be formed in the same process forming the insulating layer 130, the thickness of the side surface protector 133B formed on the first uneven surface NVN1 may be generally the same as the thickness of the side surface protector 133B formed on the second uneven surface NVN2. Accordingly, a horizontal direction distance between the first side surface 110SA and the second exposed side surface 133B2, referred to as a fourth thickness T4, may be greater than the second thickness T2.

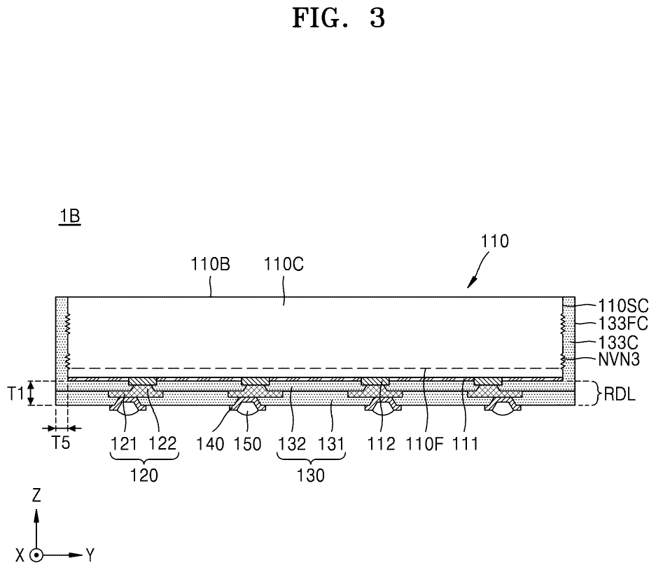

FIG. 3 is a cross-sectional view of a semiconductor package 1B according to an embodiment. Descriptions of elements that were described previously in relation to FIG. 1 may be omitted.

In the semiconductor package 1B only a single sawing process, referred to herein as the first sawing process, may be performed on the semiconductor substrate 110C, unlike the semiconductor package 1 and the semiconductor package 1A described previously. By using only a single sawing process, a single uneven surface, referred to as third uneven surface NVN3 herein, may be formed on the side surface of the semiconductor substrate 110C. A side surface protector 133C may cover a third side surface 110SC, which is the side surface of the semiconductor substrate 110C including the third uneven surface NVN3.

The side surface protector 133C may include a third exposed side surface 133FC generally parallel to the third side surface 110SC. The third exposed side surface 133FC, which is a side surface exposed external to the semiconductor package 1B is opposite to the surface of the side surface protector 133C in contact with the third uneven surface NVN3, may have an even surface without unevenness (e.g., a smooth surface). In other words, a crack occurring due to processes such as a sawing process may not be formed in the third exposed side surface 133FC. The distance between the third side surface 110SC and the third exposed side surface 133FC, referred to as a fifth thickness T5, and which is the horizontal direction thickness of the side surface protector 133C covering the third side surface 110SC, may be less than the vertical direction thickness of the insulating layer 130, referred to as a first thickness T1.

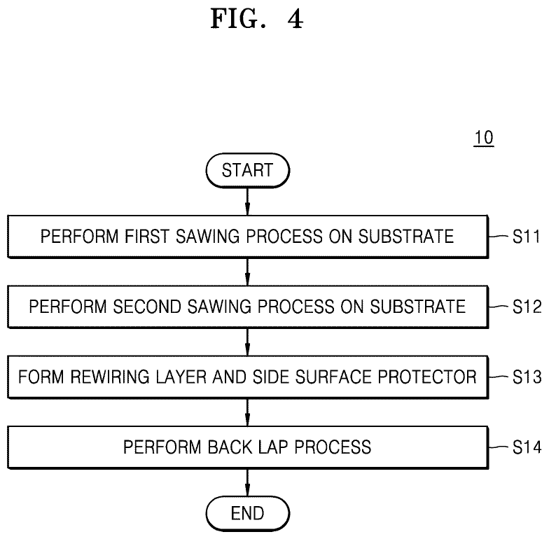

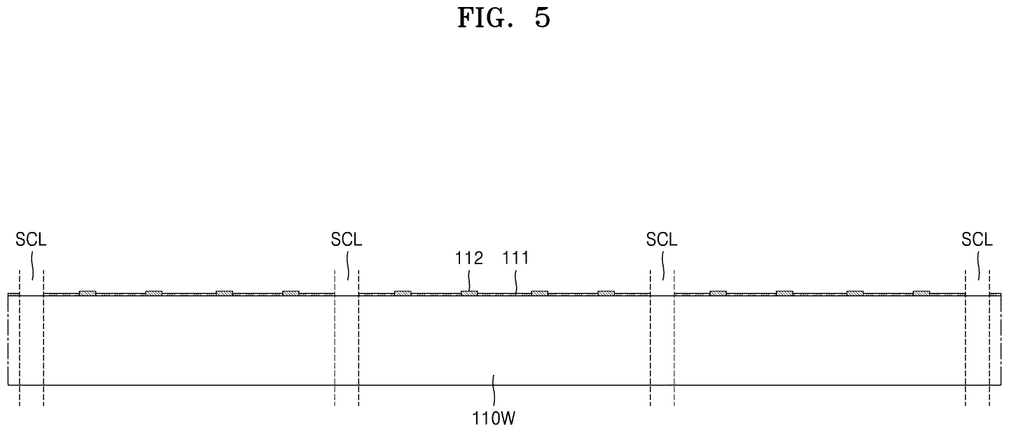

FIG. 4 is a flowchart of a method 10 of manufacturing a semiconductor package, according to an embodiment. FIGS. 5 through 9 are cross-sectional views illustrating the method 10 of manufacturing a semiconductor package in sequence, according to embodiments. Descriptions of elements that were described previously in relation to FIG. 1 may be omitted.

Referring to FIG. 4, the method 10 of manufacturing a semiconductor package according to an embodiment may include performing the first sawing process on a semiconductor substrate 110W (S11), performing the second sawing process on the semiconductor substrate 110W (S12), forming the rewiring structure RDL and the side surface protector 133A on the semiconductor substrate 110W (S13), and performing a back-lap process on the semiconductor substrate 110W (S14). The method 10 of manufacturing a semiconductor package according to embodiments is described based on the semiconductor package 1 described above, however, in a similar manner, the method of manufacturing a semiconductor package is applicable to other semiconductor packages such as the semiconductor package 1A semiconductor package 1B described above.

Referring to FIGS. 4 and 5, the passivation layer 111 and the plurality of chip pads 112 may be formed on the semiconductor substrate 110W using available semiconductor manufacturing processes. On the semiconductor substrate 110W, an imaginary scribe lane SCL may be prepared for subsequent processes. For example, the semiconductor substrate 110W may include a wafer.

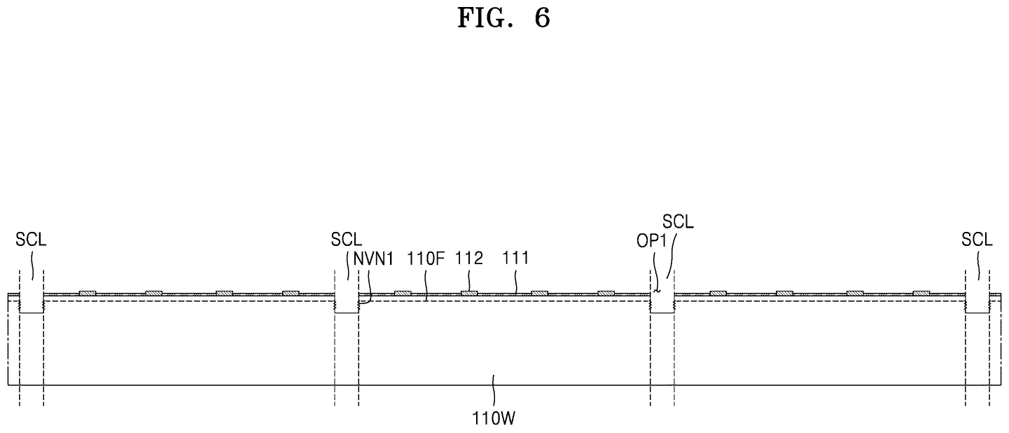

Referring to FIGS. 4 and 6, the first sawing process may be performed along the scribe lane SCL on the semiconductor substrate 110W to form a first opening OP1. The first sawing process and the second sawing process may be performed in the semiconductor package 1 according to an embodiment. However, only the first sawing process may be performed such as in the manufacturing of semiconductor package 1B according to another embodiment. The depth of an opening formed by using the first sawing process and whether to perform the second sawing process may be selected according to need by of one of ordinary skill in the art. By using the first sawing process, the first uneven surface NVN1 may be formed on the first opening OP1. This operation may correspond to the performing of the first sawing process on the semiconductor substrate 110W (S11).

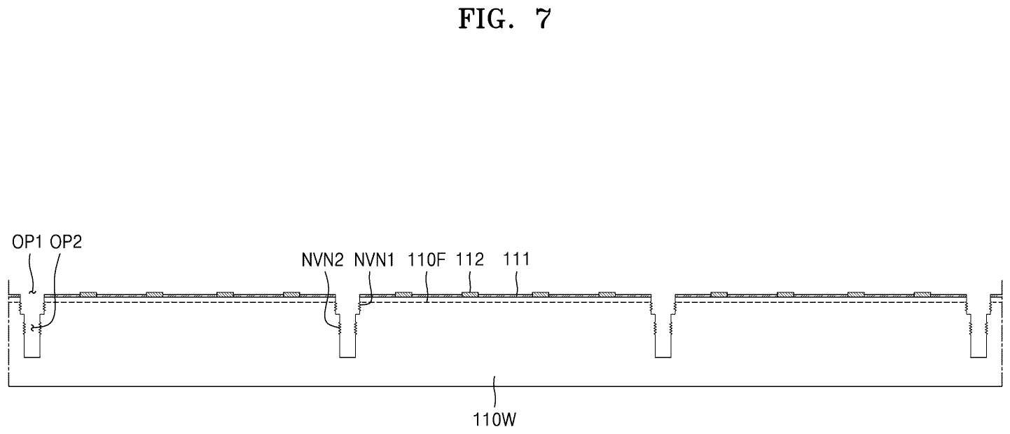

Referring to FIGS. 4 and 7, the second sawing process may be performed on the first opening OP1, which has been formed by performing the first sawing process along the scribe lane SCL on the semiconductor substrate 110W, to form a second opening OP2. The second uneven surface NVN2 may be formed in the second opening OP2 formed by using the second sawing process. A width of the second opening OP2 may be less than a width of the first opening OP1 formed by using the first sawing process. In addition, individualization of a semiconductor device may not be obtained by using the second sawing process, and may be implemented by using the back lap process to be described below, and by adjusting a depth of the second sawing process. This operation may correspond to the performing of the second sawing process on the semiconductor substrate 110W (S12).

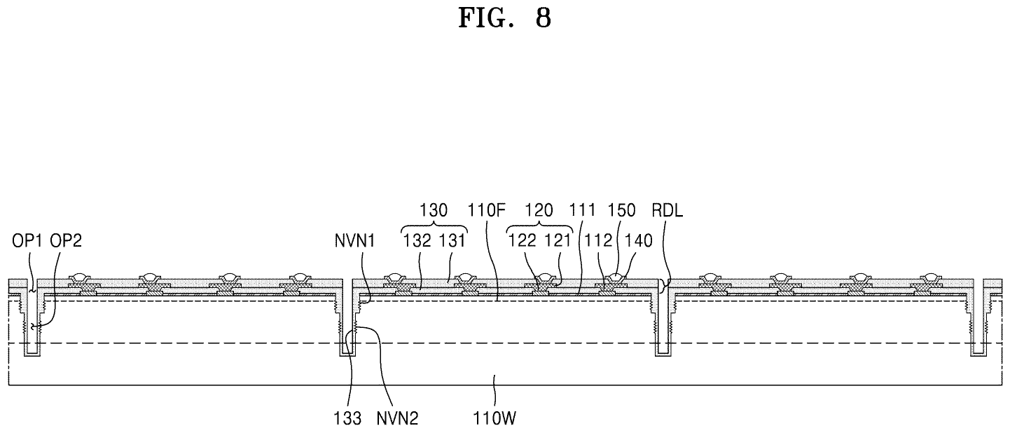

Referring to FIGS. 4 and 8, one or more of the insulating layer 130, the plurality of rewiring patterns 120, the plurality of lower connection pads 140, and the plurality of external connection terminals 150, which constitute the rewiring structure RDL, may be formed. When the insulating layer 130 of the rewiring structure RDL is formed in the semiconductor substrate 110W, at the same time, an opening side surface insulating layer 133 may also be formed in the first opening OP1 and the second opening OP2 formed in the semiconductor substrate 110W. The opening side surface insulating layer 133 formed in the first opening OP1 and the second opening OP2 may be formed together in a process, in which the insulating layer 130 is formed, within a range in which each of the first opening OP1 and the second opening OP2 is not blocked. The insulating layer 130 of the rewiring structure RDL may be formed by using a coating process, such as a spin coating process and a slit coating process, a photo patterning process, and a curing process. In the process of forming the insulating layer 130, a thickness of the opening side surface insulating layer 133 formed in the first opening OP1 and the second opening OP2 may be less than the thickness of the insulating layer 130 of the rewiring structure RDL. The opening side surface insulating layer 133 may become the side surface protector 133A by using the back lap process to be described below. This operation may correspond to forming the rewiring structure RDL and the side surface protector 133A on the semiconductor substrate 110W (S13).

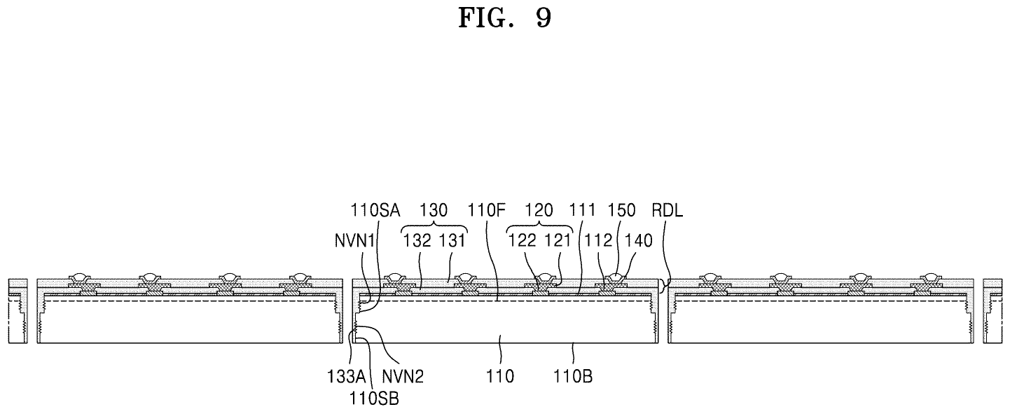

Referring to FIGS. 4 and 9, a surface opposite to the surface on which the rewiring structure RDL of the semiconductor substrate 110W is formed, may be removed by the back lap process. This operation may correspond to the performing of the back lap process on the semiconductor substrate 110W (S14).

In the back lap process, the semiconductor substrate 110W may be individualized and divided into a plurality of semiconductor packages. Because the first and second sawing processes are performed before the back lap process as described above, a process of sawing tape coating which may be required in other individualization processes in which the first and second sawing processes are performed after the back lap process, may not be required. Accordingly, the process may be simplified, and due to the simplification, the economy of manufacturing a semiconductor package may be improved. In addition, because the back lap process is performed after sawing processes, a vertical thickness of the semiconductor device 110 may be determined after the sawing processes. Thus, the vertical thickness of the semiconductor device 110 included in the semiconductor package 1 may be adjusted easily as needed, compared to the process sequence in which the sawing process is performed after the back lap process. Because the sawing process is performed before the rewiring structure RDL is formed, the insulating layer 130 constituting the rewiring structure RDL may not need to be sawed due to a process sequence, and the degree of completeness of the rewiring structure RDL may be improved. Therefore, the reliability of the semiconductor package 1 including the rewiring structure RDL may be enhanced.

While the inventive concept has been particularly shown and described with reference to embodiments thereof, it will be understood that various changes in form and details may be made therein without departing from the spirit and scope of the following claims.

What is claimed is:

1. A semiconductor package comprising:
a rewiring structure including a rewiring pattern and at least one insulating layer;
a semiconductor device provided on the rewiring structure and electrically connected to the rewiring pattern; and
a side surface protector covering a first side surface of the semiconductor device and extending to a side surface of the rewiring structure,
wherein an upper surface of the semiconductor device, which is opposite to a lower surface of the semiconductor device facing the rewiring structure, and an upper surface of the side surface protector are at the same vertical level and are coplanar with each other, and the side surface protector extends from the insulating layer of the rewiring structure.

2. The semiconductor package of claim 1,
wherein the first side surface of the semiconductor device has a first uneven surface, the side surface protector covers the first side surface and the first uneven surface, and a first exposed side surface of the side surface protector, which is opposite to a surface in contact with the first side surface, has an even surface without unevenness.

3. The semiconductor package of claim 2,
wherein the semiconductor device has a second side surface protruding beyond the first side surface, the second side surface has a second uneven surface, the side surface protector covers the second side surface and the second uneven surface, and a second exposed side surface of the side surface protector, which is opposite to a surface in contact with the second side surface, has an even surface without unevenness.

4. The semiconductor package of claim 3, wherein the first exposed side surface is coplanar with the second exposed side surface.

5. The semiconductor package of claim 3,
wherein the second exposed side surface protrudes beyond the first exposed side surface in a side direction.

6. The semiconductor package of claim 2, wherein the first uneven surface comprises cracks resulting from a singulation process of the semiconductor device.

7. The semiconductor package of claim 1, wherein the insulating layer and the side surface protector are comprised of the same material.

8. The semiconductor package of claim 7, wherein the insulating layer and the side surface protector are comprised of a photo imageable dielectric (PID) material.

9. The semiconductor package of claim 2,
wherein a vertical thickness of the insulating layer constituting the rewiring structure is greater than a horizontal distance between the first exposed side surface of the side surface protector and the first side surface.

10. The semiconductor package of claim 3,
wherein a vertical thickness of the insulating layer constituting the rewiring structure is greater than a horizontal distance between the first exposed side surface of the side surface protector and the first side surface, and
wherein a horizontal distance between the second exposed side surface of the side surface protector and the second side surface is equal to or less than the horizontal distance between the first exposed side surface of the side surface protector and the first side surface.

11. The semiconductor package of claim 10,
wherein a horizontal distance between the second exposed side surface of the side surface protector and the first side surface is greater than the horizontal distance between the first exposed side surface of the side surface protector and the first side surface.

12. The semiconductor package of claim 9, wherein the horizontal distance between the first exposed side surface of the side surface protector and the first side surface is about 5 μm to about 10 μm.

13. A method of manufacturing a semiconductor package, the method comprising:
performing a first singulation process on a substrate that includes devices formed on the substrate;
forming a rewiring layer (RDL) on the substrate and a side surface protector on a region on the substrate where the first singulation process has been performed; and
performing a back lap process on a rear surface of the substrate.

14. The method of claim 13, further comprising,
after the first singulation process is completed,
performing a second singulation process in a region where the first singulation process has been performed.

15. The method of claim 13, further comprising,
after both the RDL and the side surface protector have been formed,
forming a connection terminal on the RDL.

16. The method of claim 14,
wherein a first uneven surface is formed on at least a portion of a first side surface of the substrate, on which the first singulation process has been performed,
wherein a second uneven surface is formed on at least a portion of a second side surface of the substrate, on which the second singulation process has been performed, and
wherein the side surface protector covers both the first uneven surface and the second uneven surface, and
wherein a first exposed side surface of the side surface protector that is opposite to a surface in contact with the first side surface and a second exposed side surface that is opposite to a surface in contact with the second side surface of the side surface protector, have even surfaces.

17. The method of claim 16,
wherein the first exposed side surface and the second exposed side surface extend toward each other and, the second exposed side surface protrudes beyond than the first exposed side surface in a side direction.

18. The method of claim 13,
wherein, in the performing of the back lap process, a surface of the substrate on which the back lap process has been performed while a portion of the side surface protector is simultaneously removed is coplanar with one surface of the side surface protector on which the back lap process has been performed.

19. A semiconductor package comprising:
a rewiring structure including a rewiring pattern comprising a rewiring via pattern and a rewiring line pattern, and at least one insulating layer;
a semiconductor device provided on the rewiring structure and electrically connected to the rewiring pattern; and
a side surface protector covering a first side surface of the semiconductor device, a first uneven surface included in the first side surface, a second side surface protruding beyond the first side surface, and a second uneven surface included in the second side surface,
wherein an upper surface of the semiconductor device opposite to a lower surface of the semiconductor device facing the rewiring structure and an upper surface of the side surface protector are at the same vertical level and are coplanar with each other, and the side surface protector extends from the insulating layer of the rewiring structure,
wherein a first exposed side surface of the side surface protector that is opposite to a surface in contact with the first side surface has an even surface without unevenness, and a second exposed side surface of the side surface protector that is opposite to a surface in contact with the second side surface, has an even surface without unevenness,
wherein the first exposed side surface is coplanar with the second exposed side surface, and the surfaces of the first exposed side surface and the second exposed side surface extend toward one another,
wherein the first uneven surface comprises cracks resulting from a singulation process of the semiconductor device, and
wherein the insulating layer and the side surface protector are comprised of the same material.

20. The semiconductor package of claim 19,
wherein the insulating layer and the side surface protector comprise a photo imageable dielectric (PID) material,
wherein a thickness of the insulating layer constituting the rewiring structure is greater than a horizontal distance between the first exposed side surface of the side surface protector and the first side surface, and
wherein the horizontal distance is between the range of 5 μm to 10 μm.
